(19) United States
(12) Patent Application Publication
(10) Pub. No.: US 2020/0068721 A1
(43) Pub. Date: Feb. 27, 2020

(54) PACKAGE STRUCTURE AND MANUFACTURING METHOD THEREOF

(71) Applicant: Unimicron Technology Corp., Taoyuan (TW)

(72) Inventors: Kai-Ming YANG, Hsinchu County (TW); Chen-Hao LIN, Keelung City (TW); Wang-Hsiang TSAI, Taoyuan City (TW); Cheng-Ta KO, Taipei City (TW)

(21) Appl. No.: 16/672,512

(22) Filed: Nov. 3, 2019

Related U.S. Application Data
(63) Continuation-in-part of application No. 15/701,435, filed on Sep. 11, 2017.
Application No. 15/701,435 is a continuation-in-part of application No. 15/391,861, filed on Dec. 28, 2016.
Application No. 15/391,861 is a continuation-in-part of application No. 14/602,656, filed on Jan. 22, 2015, now Pat. No. 9,781,843.
Application No. 14/602,656 is a division of application No. 13/604,968, filed on Sep. 6, 2012, now Pat. No. 8,946,564.

(30) Foreign Application Priority Data
Oct. 31, 2011 (TW) 100139667
Oct. 20, 2016 (TW) 105133848
Jul. 14, 2017 (TW) 106123710
Aug. 26, 2019 (TW) 108130496

(51) Int. Cl. H05K 3/40; H05K 1/18; H05K 1/11; H05K 1/14; H01L 23/14; H01L 23/15; H01L 23/498; H01L 21/48; H01L 21/768

(52) U.S. Cl. CPC H05K 3/4038; H05K 2201/10674; H05K 1/11; H05K 1/142; H01L 23/147; H01L 23/15; H01L 23/49822; H01L 23/49827; H01L 21/4846; H05K 1/112; H01L 21/76898; Y10T 29/49165; Y10T 29/4913; Y10T 29/49146; H01L 2924/014; H01L 2224/16225; H01L 2924/00014; H01L 2224/131; H01L 2224/16237; H01L 2224/73204; H01L 2224/32225; H01L 2924/15311; H01L 23/49816; H05K 1/183

(57) ABSTRACT

A package structure, includes a metal layer, an insulating composite layer disposed thereon, a sealant bonded on the insulating composite layer, a chip embedded in the sealant, a circuit layer structure disposed on the sealant and the chip, and a protecting layer. The chip has a plurality of electrode pads exposed from the sealant. The circuit layer structure includes at least one dielectric layer and at least one circuit layer. The dielectric layer has a plurality of conductive blind vias. The dielectric layer and the sealant are made of the same material. The circuit layer is disposed on the dielectric layer and extends into the conductive blind vias, and the bottommost circuit layer is electrically connected to the electrode pads through the conductive blind vias. The protecting layer is formed on the circuit layer structure and has a plurality of openings exposing a portion of the circuit layer structure.

### CROSS-REFERENCE TO RELATED APPLICATION

This application is a continuation-in-part of U.S. application Ser. No. 15/701,435, filed Sep. 11, 2017, now pending, which is a continuation-in-part of U.S. application Ser. No. 15/391,861, filed Dec. 28, 2016, now pending, which is a continuation-in-part of U.S. application Ser. No. 14/602,656, filed Jan. 22, 2015, now patented as U.S. Pat. No. 9,781,843, which is a divisional of U.S. application Ser. No. 13/604,968, filed Sep. 6, 2012, now patented as U.S. Pat. No. 8,946,564. The prior U.S. application Ser. No. 15/701,435 claims priority to Taiwan Application serial number 106123710, filed Jul. 14, 2017. The prior U.S. application Ser. No. 15/391,861 claims priority to Taiwan Application serial number 105133848, filed Oct. 20, 2016. The prior U.S. application Ser. No. 13/604,968 claims priority to Taiwan Application serial number 100139667, filed Oct. 31, 2011. This application also claims priority to Taiwan Application Serial Number 108130496, filed Aug. 26, 2019. The entirety of each of the above-mentioned patent applications is hereby incorporated by reference herein and made a part of this specification.

### BACKGROUND

### Field of Invention

The present disclosure relates to a package structure and a manufacturing method thereof.

### Description of Related Art

Along with the advancement in semiconductor packaging technology, there are various types of packages for semiconductor devices besides the conventional wire bonding semiconductor packaging technique. For example, one type of semiconductor devices allows a semiconductor chip having an integrated circuit (IC) to be embedded and electrically integrated with a package substrate in order to reduce the overall dimension and improve the electrical functions.

In order to satisfy the demands of shortening the wire length, reducing the overall thickness and requirements of high-frequency and miniaturization, a method of processing a chip substrate embedded on a carrier board without a coreless layer has been developed. However, since the carrier board without a coreless layer does not have a supporting hardcore plate, the carrier board is prone to warpage due to insufficient structural strength.

### SUMMARY

One purpose of the present disclosure is to provide a package structure and a manufacturing thereof for addressing the abovementioned issues.

One aspect of the present disclosure provides a package structure. The package structure comprises a metal layer, an insulating composite layer, a sealant, a chip, a circuit layer structure, and a protecting layer. The insulating composite layer is disposed on the metal layer. The sealant is bonded on the insulating composite layer. The chip is embedded in the sealant and has a plurality of electrode pads exposed through the sealant. The circuit layer structure is disposed on the sealant and the chip, in which the circuit layer structure comprises at least one dielectric layer and at least one circuit layer. The dielectric layer has a plurality of conductive blind vias. The dielectric layer and the sealant are made of the same material. The circuit layer is disposed on the dielectric layer and extends into the conductive blind vias. The bottommost circuit layer is electrically connected to the electrode pads through the conductive blind vias. The protecting layer is formed on the circuit layer structure, in which the protecting layer has a plurality of openings exposing a portion of the circuit layer structure.

In one or more embodiments of the present disclosure, the material of the dielectric layer and the sealant includes a resin, a glass fiber, and a photo-imageable dielectric material.

In one or more embodiments of the present disclosure, the resin comprises a phenolic resin, an epoxy resin, a polyimide resin and polytetrafluoroethylene.

In one or more embodiments of the present disclosure, the chip has a bottom chip surface exposed from the sealant.

In one or more embodiments of the present disclosure, the insulating composite layer comprises a composite material having an inorganic insulating material and an organic material.

In one or more embodiments of the present disclosure, the insulating composite layer is an imitation nacreous layer.

Another aspect of the present disclosure provides a method of manufacturing package structure. The method comprises steps of providing a carrier board comprising a supporting layer, a first release layer, a second release layer and a plurality of metal layers, in which the first release layer and the second release layer is respectively disposed on opposite surfaces of the supporting layer, and the metal layers are disposed on the first release layer and the second release layer; disposing an insulating composite layer on each of the metal layers; bonding an embedded chip substrate on each of the insulating composite layers, in which each of the embedded chip substrates comprises a sealant and a chip embedded in the sealant, and the chip has a plurality of electrode pads exposed from the sealant; forming a circuit layer structure on each of the embedded chip substrates, in which the circuit layer structure comprises at least one dielectric layer and at least one circuit layer, the dielectric layer has a plurality of conductive blind vias, the dielectric layer and the sealant are made of a same material, the circuit layer is located on the dielectric layer and extends into the conductive blind vias, and the circuit layer is electrically connected to the electrode pads through the conductive blind vias; and forming a protecting layer on the circuit layer structure, in which the protecting layer has a plurality of openings exposing a portion of the circuit layer structure; removing the supporting layer, the first release layer and the second release layer to form two packaging substrates; and dicing the packaging substrates to obtain a plurality of package structures.

In one or more embodiments of the present disclosure, the step of disposing an embedded chip substrate on each of the insulating composite layers comprises polishing a bottom surface of the sealant of the embedded chip substrate to expose a bottom surface of the chip, such that a polished embedded chip substrate is formed; and disposing the polished embedded chip substrate on the insulating composite layer.

In one or more embodiments of the present disclosure, the material of the dielectric layer and the sealant includes a resin, a glass fiber, and a photo-imageable dielectric material.

In one or more embodiments of the present disclosure, the resin comprises a phenolic resin, an epoxy resin, a polyimide resin and polytetrafluoroethylene.

### BRIEF DESCRIPTION OF THE DRAWINGS

The disclosure can be more fully understood by reading the following detailed description of the embodiment, with reference made to the accompanying drawings as follows.

FIG. 1 illustrates a flow chart of a method of manufacturing a package structure according to one embodiment of the present disclosure.

FIG. 2 through FIG. 9 illustrates schematic cross-sectional views of a package structure during various processing stages according to one embodiment of the present disclosure.

FIG. 10 illustrates cross-sectional views of a package structure according to another embodiment of the present disclosure.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

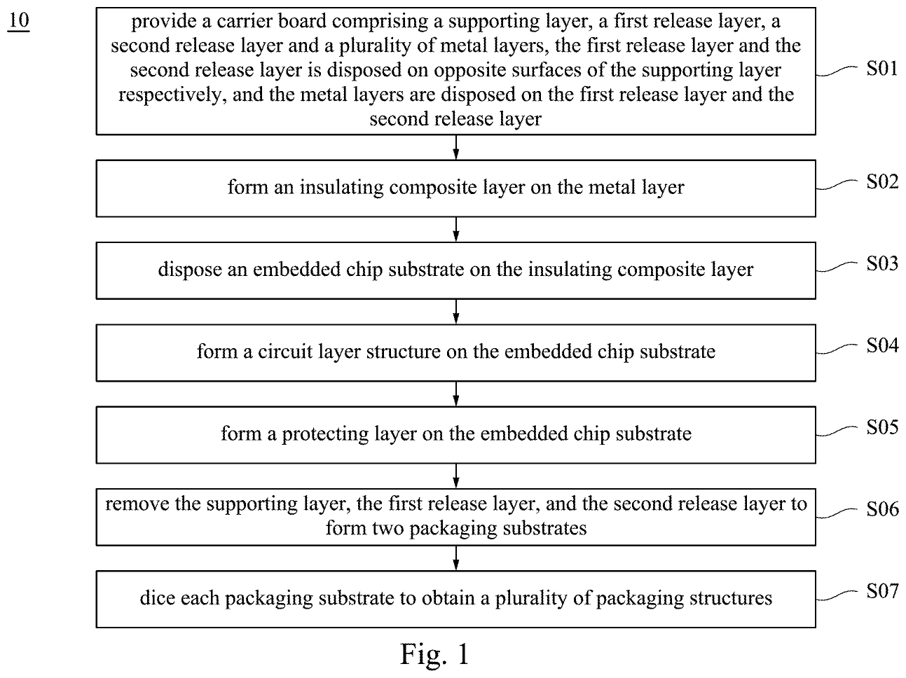

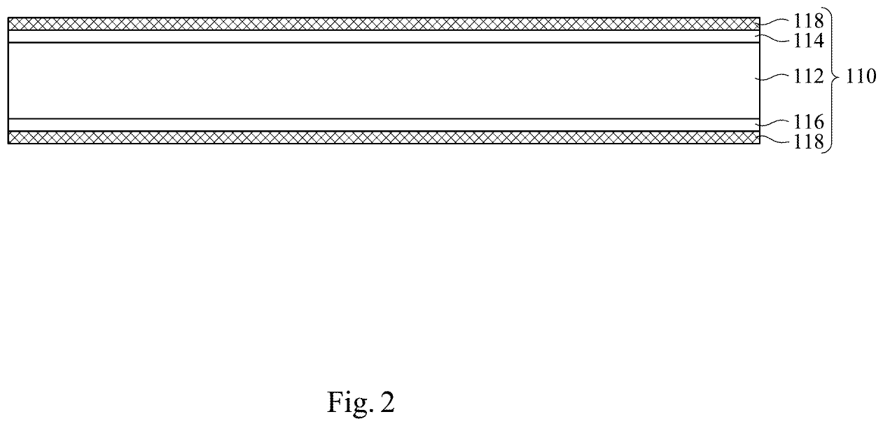

One aspect of the present disclosure provides a method of manufacturing a package structure. The package structure formed thereof has a high structural strength and is capable of preventing warpage of the carrier board, thereby increasing the process yield and reliability of the package structure. FIG. 1 illustrates a flow chart of a method 10 of manufacturing a package structure 100 according to one embodiment of the present disclosure. FIG. 2 through FIG. 9 illustrates schematic cross-sectional views of the package structure 100 during various processing stages of the method 10 according to some embodiments of the present disclosure. As shown in FIG. 1, the method 10 includes step S01 to step S07.

First, at step S01, a carrier board 110 as shown in FIG. 2 is provided. Specifically, the carrier board 110 includes a supporting layer 112, a first release layer 114, a second release layer 116, and a plurality of metal layers 118. The first release layer 114 is disposed on a surface of the supporting layer 112, and the second release layer 116 is disposed on the opposite surface of the supporting layer 112. The metal layers 118 are disposed on the first release layer 114 and the second release layer 116. In some embodiments, the supporting layer 112 may be made of an organic polymeric material such as bismaleimide triazine (BT). In some embodiments, the supporting layer 112 may be a copper clad laminate (CCL) (not shown) with a dielectric material (for example, a prepreg) disposed thereon. In some embodiments, the first release layer 114 and/or the second release layer 116 may be a release film. In other embodiments, the first release layer 114 or the second release layer 116 may be such as a copper foil bonded with a release layer available from Mitsui, Nippon-Denk, Furukawa or Olin. In some embodiments, a thickness of the metal layer 118 may range from 1 μm to 10 μm, but is not limited thereto. The metal layers 118 may be made of copper, aluminum, nickel, silver, gold or an alloy thereof, but is not limited thereto. In other embodiments, the metal layers 118 may be a single layer or a stack of a plurality of metal layers 118.

In other embodiments, an additional metal layer (not shown) is sandwiched between the supporting layer 112 and the first release layer 114 or otherwise between the supporting layer 112 and the second release layer 116. A thickness of the additional metal layer may range from 5 μm to 40 μm. The additional metal layer and the metal layer 118 may be made of the same or different material and composition, such as copper, aluminum, nickel, silver, gold, or an alloy thereof, but is not limited thereto.

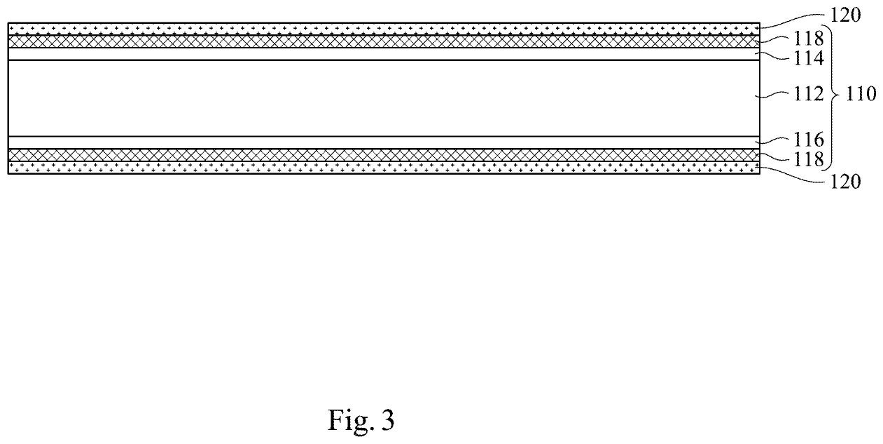

At step S02, an insulating composite layer 120 is formed on the metal layers 118, as shown in FIG. 3. It is understood that step S02 and the following step S03 to step S07 may be performed on a single surface or both opposite surfaces of the carrier board 110. In the present embodiment, a double-sided fabrication of the carrier board 110 is described. In some embodiments, the insulating composite layer 120 comprises a composite material, and the composite material comprises an inorganic insulating material and an organic material. In detail, the inorganic insulating material may include a ceramic material, such as zirconium dioxide, silicon carbide, silicon nitride, aluminum oxide, silicon oxide or a combination thereof, and the organic material may include a polymer, such as epoxy resins, polyimides, liquid crystal polymers, methacrylate resins, polyacrylate resins, allyl resins, vinyl phenyl resins, polysiloxane resins, polyolefin resins, polyurethane resins, polyether resins, or a combination thereof. In one example, the ceramic material may be ceramic flakes, ceramic powder, ceramic microparticles, or ceramic nanoparticles, but is not limited thereto.

In an example where the inorganic insulating material is ceramic powder, the insulating composite layer 120, which is a composite consisting of ceramic powder and polymer, may be prepared by impregnating ceramic powder in a polymer using a vacuum impregnation technique. In an example where the polymer is a photosensitive composition of epoxy resins and polyimide resins, the insulating composite layer 120 is disposed on the metal layers 118 by a thermal bonding process or a vacuum impregnation technique with a follow-up UV irradiation and heating process.

In an example where the inorganic insulating material is ceramic flakes, the insulating composite layer 120 may be such as an imitation nacreous layer. The insulating composite layer 120, which is a composite consisting of ceramic flake and polymer, may be prepared by impregnating ceramic flake in a polymer using a vacuum impregnation technique. However, the preparation method of the insulating composite layer 120 is not limited thereto, and any other techniques capable of forming a composite material consisting of a polymer and a ceramic material are suitable. In the example where the inorganic insulating material is ceramic flakes, the insulating composite layer 120 comprises an organic matter (for example, a polymer) and an inorganic matter (for example, ceramic flakes), and the adhesion between the organic matter and the inorganic matter results in a sheet-like or a brick-like (or a combination thereof) laminated microscopic structural arrangement of the ceramic flake in the insulating composite layer 120. The structural arrangement suppresses the conduction of the lateral breaking force, resulting in a significant increase in hardness. Thus, the ceramic flake is relatively hard and has a high elasticity modulus, thereby increasing the strength, brittleness and toughness of the ceramic.

The Young's modulus of the insulating composite layer 120 may range from 20 GPa to 100 GPa. Compared with conventional dielectric layers (with Young's modulus not more than 10 GPa) and conventional packaging material (with Young's modulus not more than 20 GPa), the insulating composite layer 120 of the present example has an excellent hardness which can enhance the structural strength of the package structure.

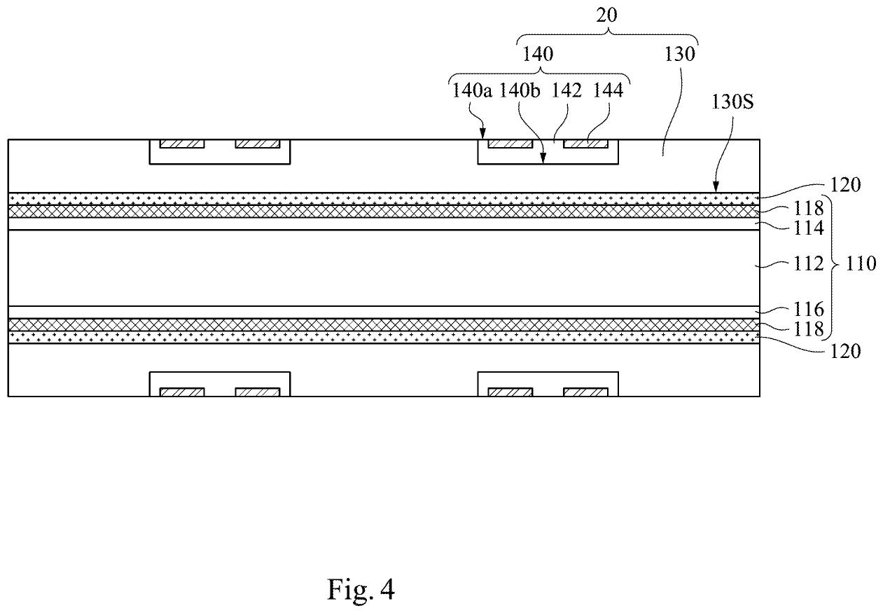

At step S03, an embedded chip substrate 20 is bonded on the insulating composite layer 120, as shown in FIG. 4. Specifically, the embedded chip substrate 20 may be disposed on two opposite surfaces of the insulating composite layer 120. The embedded chip substrate 20 includes a sealant 130 with a chip 140 embedded therein. The chip 140 has a first surface 140a and a second surface 140b opposite thereto. The chip 140 includes a chip substrate 142 and a plurality of electrode pads 144. In some embodiments, the electrode pads 144 are exposed from the first surface 140a, while the second surface 140b is covered by the sealant 130. It is noted that the electrode pads 144 are also exposed from the sealant 130. The chip 140 may be electronic components of various integrated circuits, including discrete components, active or passive elements, digital or analog circuits, ECM, DRAM, SRAM, optoelectronic devices, micro electro mechanical systems (MEMS), microfluidic systems, or physical sensors that measures the variation of some physical quantities such as heat, light, or pressure, RF circuits, accelerators, gyroscopes, micro actuators, surface acoustic component, pressure sensors, or the like, but is not limited thereto. The chip 140 shown in FIG. 1 is merely illustrative, and the actual length, width, height and dimensions of the chip 140 may vary depending on product requirements.

In various embodiments, the sealant 130 may include a resin and a glass fiber. For example, the resin may comprise a phenolic resin, an epoxy resin, a polyimide resin and polytetrafluoroethylene. Alternatively, the sealant 130 may comprise a photo-imageable dielectric material.

In some embodiments, the embedded chip substrate 20 is bonded on the insulating composite layer 120 by adding an adhesive layer (not shown) therebetween. Specifically, the adhesive layer may be disposed on a bottom surface 20S of the embedded chip substrate 20, and the embedded chip substrate 20 is then bonded on the insulating composite layer 120. In one example, the adhesive layer may include a heat sink with high heat dissipation or high-temperature resistance, but is not limited thereto.

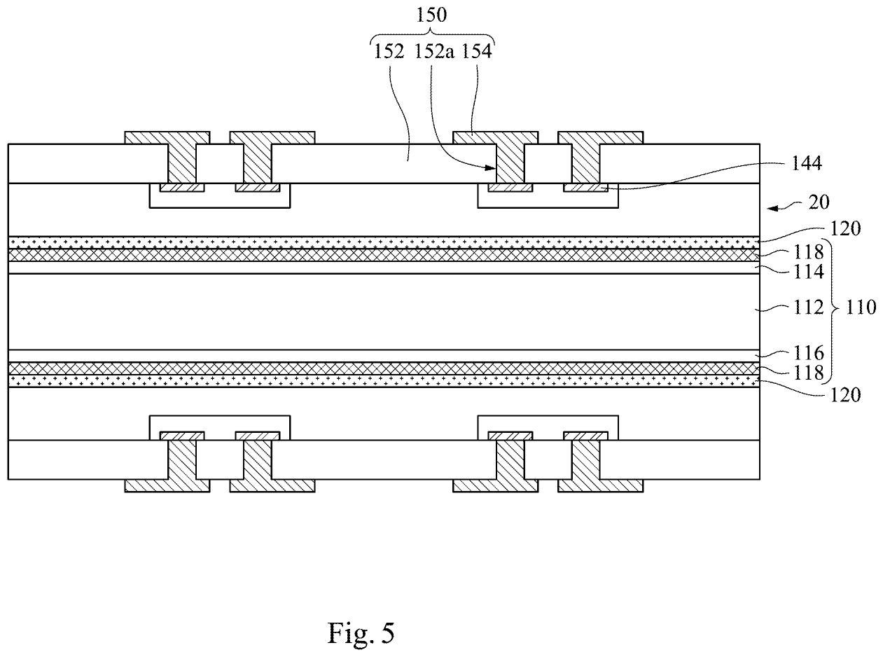

At step S04, a first circuit layer structure 150 is formed on the embedded chip substrate 20, as shown in FIG. 5. Specifically, the first circuit layer structure 150 includes at least one first dielectric layer 152 and at least one first circuit layer 154. It is understood that the circuit layer structure 150 at least includes one dielectric layer and one circuit layer, and one skilled in the art can select the layer number of the dielectric layer and the circuit layer based on actual needs. The first dielectric layer 152 has a plurality of first conductive blind vias 152a. The first circuit layer 154 is disposed on the first dielectric layer 152 and connects or extends into the first conductive blind vias 152a. The bottommost first circuit layer 154 is electrically connected to the electrode pads 144 through the first conductive blind vias 152a.

In some embodiments, the first dielectric layer 152 may be made of resin and glass fiber. For example, the resin may be phenolic resins, epoxy resins, polyimide resins or polytetrafluoroethylene. Alternatively, the first dielectric layer 152 may include a photo-imageable dielectric (PID). It is noted that in the present disclosure, the sealant 130 and the first dielectric layer 152 are made of the same material and composition. Compared with the conventional technique where the sealant and the dielectric layer are made of different materials and compositions, the sealant 130 and the first dielectric layer 152 in the present disclosure have the same material and composition, thereby preventing uneven tension resulted from the contacting interface of different materials, thereby increasing the structural strength of the package structure. Therefore, the package structure is prevented from warpage during the subsequent processing on the embedded chip substrate.

In some embodiments, the first dielectric layer 152 may be formed by a lamination process, a coating process or other suitable processes. In some embodiments, the blind holes for the formation of the first conductive blind vias 152a may be formed in the first dielectric layer 152 by using a laser ablation process, or otherwise an exposure and developing process in the case where the first dielectric layer 152 is a photo-imageable dielectric, but is not limited thereto.

In some embodiments, the method of forming the first circuit layers 154 includes but not limited to forming a photoresist layer such as a dry film (not shown) on the first dielectric layers 152. The photoresist layer is then patterned by a lithography process, such that a portion of the first dielectric layers 152 is exposed. Next, an electroplating process is performed, and the photoresist layer is then removed to form the first circuit layers 154. In one example, the first circuit layers 154 and the first conductive blind vias 152a may be made of copper. In other embodiments, before the formation of the first circuit layers 154, a seed layer (not shown) may be formed on the first dielectric layers 152. The seed layer may be a single-layered structure or a multilayer structure composed of sub-layers of different materials, for example, a metal multilayer having a titanium layer and a copper layer thereon. The seed layer may be formed by a physical process such as titanium and copper sputtering, or a chemical process such as chemical plating of palladium and copper and copper electroplating, but is not limited thereto.

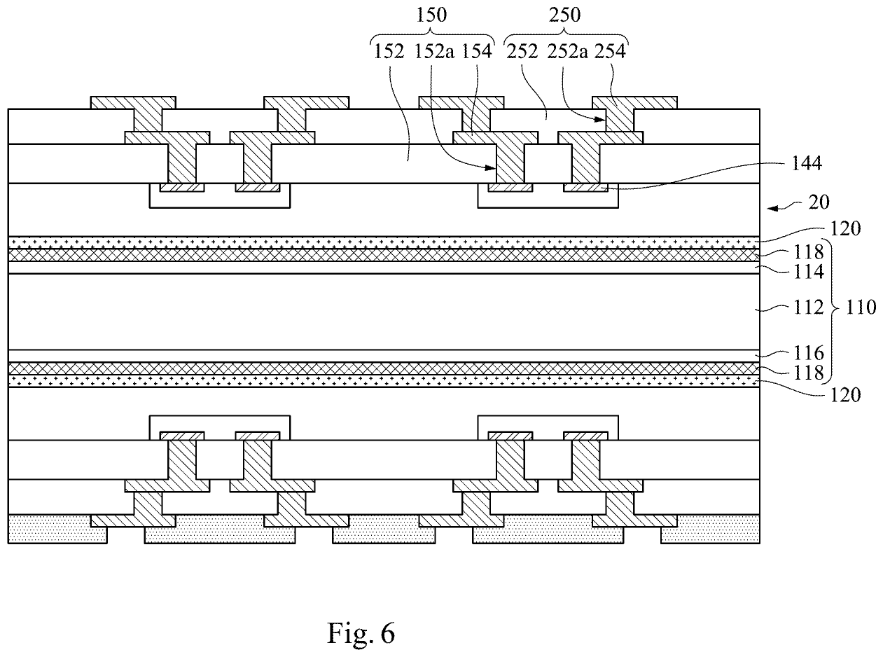

It is noted that in some other embodiments, the method 10 may also comprise a second circuit layer structure 250 over the embedded chip substrate 250, as shown in FIG. 6. Specifically, the second circuit layer structure 250 includes at least one second dielectric layer 252 and at least one second circuit layer 254. The second dielectric layer 252 has a plurality of second conductive blind vias 252a. The second circuit layer 254 is disposed on the second dielectric layer 252 and connects or extends to the second conductive blind vias 252a. The bottommost second circuit layer 254 is electrically connected to the second conductive pads 144 through the second conductive blind vias 252a. It is understood that the second circuit layer structure 250 at least includes one dielectric layer and one circuit layer, and one of ordinary skill in the art can select the layer number of the dielectric layer and the circuit layer based on actual needs.

The materials and forming processes of the second dielectric layer 252, the second circuit layers 254 and the second conductive blind vias 252a are similar to those of the first dielectric layer 152, the first circuit layers 154 and the first conductive blind vias 152a respectively, and therefore are not repeated herein. In other words, in the present disclosure, the sealant 130, the first dielectric layer 152 and the second dielectric layer 252 may be made of the same material and composition.

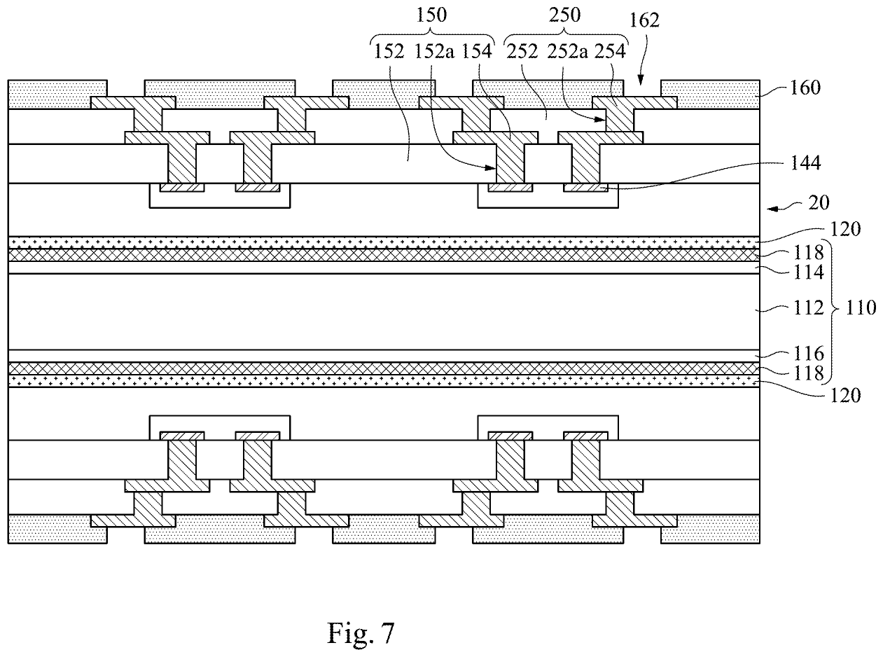

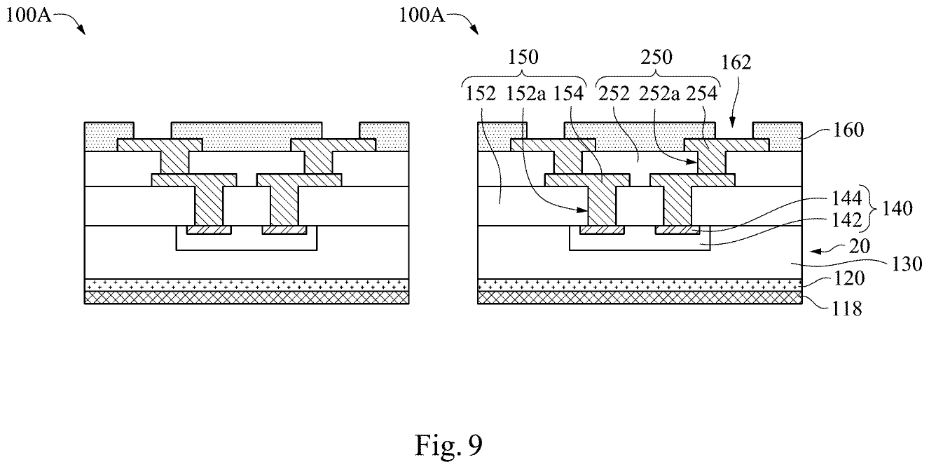

At step S05, a protecting layer 160 is formed on the second circuit layer structure 250, as shown in FIG. 7. The protecting layer 160 has a plurality of openings 162. A portion of a surface of the second circuit layer structure 250 is exposed from the openings 162. Specifically, as shown in FIG. 9, a portion of the outermost second circuit layers 254 of the second circuit layer structure 250 is exposed from the openings 162. In some embodiments, the protecting layer 160 may be made of a soldering resist material or resins, such as epoxy resins. Alternatively, the protecting layer 160 may be made of the same or similar material as the first dielectric layer 152 or the second dielectric layer 252. The protecting layer 160 may be formed by a lamination process, a printing process, a coating process, or the like.

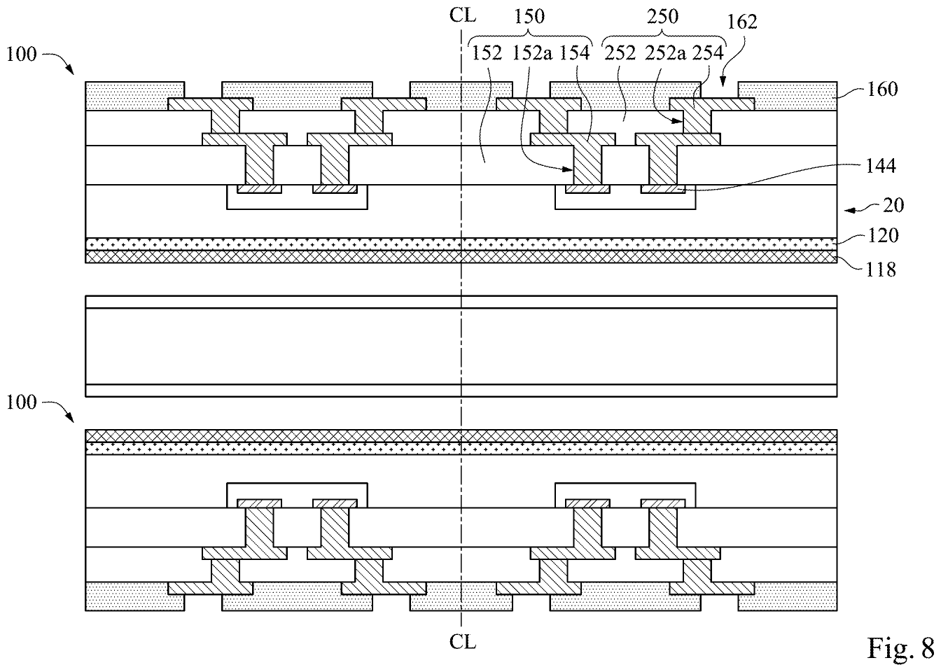

At step 06, as shown in FIG. 8, the supporting layer 112, the first release layer 114 and the second release layer 116 are removed from the structure to form two package structures 100. In the conventional single-sided manufacturing method, the supporting layer is prone to warpage due to its structural asymmetry. However, in the method 10 of the present disclosure, by means of simultaneously performing the same process on opposite surfaces of the supporting layer 112, two symmetry package structures 100 are formed, thereby preventing warpage on two ends of the supporting layer 112 and increasing the overall reliability of the package structure. In addition, the heat generated by the chip 144 can be dissipated by the heat conduction of the metal layer 118 disposed on the bottom of the package structures 100.

At step 07, as shown in FIG. 9, the package structures 100 is each diced to form a plurality of package structures 100A. In some embodiments, each of the package structure 100 is diced along a cutting line CL shown in FIG. 8 to form a plurality of package structures 100A. It is understood that in method 10, if N integers of package structures 100A can be formed from one package structure 100, 2N integers of package structures 100A can be similarly formed from two package structures 100. According, the method of the present disclosure can effectively increase the yield of production.

Another aspect of the present disclosure provides a package structure. FIG. 9 illustrates a schematic cross-sectional view of a package structure 100A according to one embodiment of the present disclosure. The package structure 100A includes a metal layer 118, an insulating composite layer 120, a sealant 130, a chip 140, a first circuit layer structure 150, and a protecting layer 160. The insulating composite layer 120 is disposed on the metal layer 118. The sealant 130 is bonded on the insulating composite layer 120. The chip 140 is embedded in the sealant 130. The chip 140 has a plurality of electrode pads 144 exposed from the sealant 130. The first circuit layer structure 150 is formed on the sealant 130 and the chip 140. The first circuit layer structure 150 includes at least one first dielectric layer 152 and at least one first circuit layer 154. The first dielectric layer 152 has a plurality of first conductive blind vias 152a. The first dielectric layer 152 and the sealant 130 are made of the same material and composition. The first circuit layers 154 is located on the first dielectric layer 152 and extends into the first conductive blind vias 152a, and the bottommost first circuit layers 154 is electrically connected to the electrode pads 144 through the first conductive blind vias 152a. It is understood that the first circuit layer structure 150 at least includes one dielectric layer and one circuit layer, and one of ordinary skill in the art may select the desired number of the dielectric layer and the circuit layer based on the actual needs. The protecting layer 160 is formed over the first circuit layers 154. The protecting layer 160 has a plurality of openings 162 exposing a portion of a surface of the first circuit layers 154.

The forming processes and the materials of the metal layer 118, the insulating composite layer 120, the sealant 130, the chip 140, the first circuit layer structure 150 and the protecting layer 160 are provided above, and therefore are not repeated herein. It is noted that the sealant 130 and the first dielectric layer 152 in the present disclosure are made of the same material and composition. Compared with the conventional technique where the sealant and the dielectric layer are made of different materials, the sealant 130 and the first dielectric layer 152 made of the same material and composition may prevent the uneven tension resulted from the contacting interface between different materials, thereby increasing the structural strength of the package structure. Therefore, the package structure is prevented from warpage during the subsequent processing on the embedded chip substrate.

In some other embodiments, the package structure 100A includes a second circuit layer structure 250. The second circuit layer structure 250 is located over the embedded chip substrate 20. The second circuit layer structure 250 includes at least one second dielectric layer 252 and at least one second circuit layer 254. The second dielectric layer 252 has a plurality of second conductive blind vias 252a. The second circuit layer 254 is disposed on the second dielectric layer 252 and connects or extends into the second conductive blind vias 252a, and the bottommost second circuit layer 254 is electrically connected to the electrode pads 144 through the second conductive blind vias 252a. It is understood that the second circuit layer structure 250 at least includes one dielectric layer and one circuit layer, and one of ordinary skill in the art may select the desired number of the dielectric layer and the circuit layer based on the actual needs. The sealant 130, the first dielectric layer 152, and the second dielectric layer 252 may be made of the same material and composition.

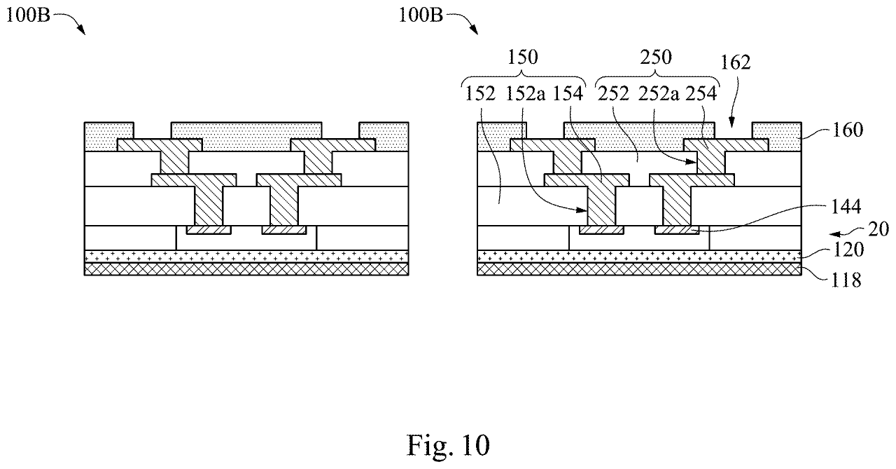

FIG. 10 illustrates a cross-sectional view of a package structure 100B according to another embodiment of the present disclosure. The manufacturing method of the package structure 100B in the present embodiment is similar to that of the package structure 100A, except that at step 03 (see FIG. 4) where the embedded chip substrate 20 is bonded on the insulating composite layer 120, the manufacturing method of the package structure 100B further comprises sub-steps of polishing a bottom surface of the sealant 130 to expose a bottom surface 140b (a second surface) of the chip 140, such that a polished embedded chip substrate is formed; and disposing the polished embedded chip substrate on the insulating composite layer 120. The bottom surface of the sealant 130 may be polished by a chemical mechanical polishing (CMP) process, but is not limited thereto. The polished embedded chip substrate is disposed on the insulating composite layer 120 by means of adding an adhesive layer (not shown) between the polished embedded chip substrate and the insulating composite layer 120, but is not limited thereto.

It is noted that in the package structure 100B in the present embodiment, since the bottom surface (second surface) 140b of the chip 140 is exposed from the sealant 130, the metal layer 118 can not only conduct the heat generated by the chip 140 in an more effective way to enhance the heat dissipation, and also reducing the thickness of the package structure 100B to pursuit a thin product design.

In summary, in the package structure and the manufacturing method thereof in the present disclosure, the sealant, the first dielectric layer and the second dielectric layer have the same material and composition. Therefore, compared with the conventional package structure where the sealant and the dielectric layer are made of different materials, the package structure of the present disclosure can prevent uneven tension resulted from the contacting interface of the different materials, thereby increasing the structural strength, such that the embedded chip structure is prevented from warpage during the subsequent processing.

In addition, in the package structure and the manufacturing method thereof in the present disclosure, a package substrate is formed on the insulating composite layer. In other words, the insulating composite layer can be regarded as a strengthened layer, which has a high hardness compared with a conventional dielectric layer and a packaging material. Thus, the overall structural strength of the package structure and the manufacturing method thereof of the disclosure can be enhanced through the insulating composite layer, so as to prevent the warpage of the carrier board, thereby increasing the process yield and the reliability of the package structure.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. A package structure, comprising:
a metal layer;
an insulating composite layer disposed on the metal layer;
a sealant bonded on the insulating composite layer;
a chip embedded in the sealant, the chip having a plurality of electrode pads exposed from the sealant;
a circuit layer structure disposed on the sealant and the chip, wherein the circuit layer structure comprises at least one dielectric layer and at least one circuit layer, the dielectric layer has a plurality of conductive blind vias, the dielectric layer and the sealant are made of a same material, the circuit layer is disposed on the dielectric layer and extends into the conductive blind vias, and the bottommost circuit layer is electrically connected to the electrode pads through the conductive blind vias; and
a protecting layer formed on the circuit layer structure, wherein the protecting layer has a plurality of openings exposing a portion of a surface of the circuit layer structure.

2. The package structure of claim 1, wherein a material of the dielectric layer and the sealant includes a resin, a glass fiber, and a photo-imageable dielectric material.

3. The package structure of claim 2, wherein the resin comprises a phenolic resin, an epoxy resin, a polyimide resin and polytetrafluoroethylene.

4. The package structure of claim 1, wherein the chip has a bottom chip surface exposed from the sealant.

5. The package structure of claim 1, wherein the insulating composite layer comprises a composite material, and the composite material comprises an inorganic insulating material and an organic material.

6. The package structure of claim 1, wherein the insulating composite layer is an imitation nacreous layer.

7. A method of manufacturing package structure, comprising steps of:
providing a carrier board comprising a supporting layer, a first release layer, a second release layer and a plurality of metal layers, wherein the first release layer and the second release layer is respectively disposed on opposite surfaces of the supporting layer, and the metal layers are disposed on the first release layer and the second release layer;
disposing an insulating composite layer on each of the metal layers;
bonding an embedded chip substrate on the insulating composite layer, wherein the embedded chip substrate comprises a sealant and a chip embedded in the sealant, and the chip has a plurality of electrode pads exposed from the sealant;
forming a circuit layer structure on the embedded chip substrate, wherein the circuit layer structure comprises at least one dielectric layer and at least one circuit layer, the dielectric layer has a plurality of conductive blind vias, the dielectric layer and the sealant are made of a same material, the circuit layer is located on the dielectric layer and extends into the conductive blind vias, and the circuit layer is electrically connected to the electrode pads through the conductive blind vias; and
forming a protecting layer on the circuit layer structure, wherein the protecting layer has a plurality of openings exposing a portion of a surface of the circuit layer structure;
removing the supporting layer, the first release layer and the second release layer to form two packaging substrates; and
dicing the packaging substrates to form a plurality of package structures.

8. The method of claim 7, wherein the step of disposing the embedded chip substrate on the insulating composite layer comprises:
polishing a bottom surface of the sealant of the embedded chip substrate to expose a bottom surface of the chip, such that a polished embedded chip substrate is formed; and
disposing the polished embedded chip substrate on the insulating composite layer.

9. The method of claim 7, wherein the material of the dielectric layer and the sealant includes a resin, a glass fiber, and a photo-imageable dielectric material.

10. The method of claim 9, wherein the resin comprises a phenolic resin, an epoxy resin, a polyimide resin and polytetrafluoroethylene.
